(19) United States
(12) Patent Application Publication
(10) Pub. No.: US 2024/0346198 A1
(43) Pub. Date: Oct. 17, 2024

(54) METHOD AND SYSTEM FOR IDENTIFYING A KINEMATIC CAPABILITY IN A VIRTUAL KINEMATIC DEVICE

(71) Applicant: Siemens Industry Software Ltd., Tel Aviv (IL)

(72) Inventors: Moshe Hazan, Elad (IL); Gil Chen, Bnei Zion (IL); Shahar Zuler, Rosh Haayin (IL); Albert Harounian, Ramat Gan (IL); Diana Gospodinova, Sofia (BG)

(21) Appl. No.: 18/292,465

(22) PCT Filed: Jul. 26, 2021
(86) PCT No.: PCT/IB2021/056734

§ 371 Date: Jan. 26, 2024

(51) Int. Cl. G06F 30/17

(52) U.S. Cl. CPC G06F 30/17

(57) ABSTRACT

Systems and a method identify a kinematic capability in a virtual kinematic device. Input data are received, wherein the input data contains data on a point cloud representation of a given virtual kinematic device. A kinematic analyzer is applied to the input data, wherein the kinematic analyzer is modeled with a function trained by a machine learning algorithm and the kinematic analyzer generates output data. The output data contains data for associating a subset of the points of the point cloud representation to a set of kinematic descriptors of at least one link identified on the point cloud representation of the given virtual kinematic device. From the output data at least one identified kinematic capability is determined in the given virtual kinematic device.

### TECHNICAL FIELD

The present disclosure is directed, in general, to computer-aided design, visualization, and manufacturing (“CAD”) systems, product lifecycle management (“PLM”) systems, product data management (“PDM”) systems, production environment simulation, and similar systems, that manage data for products and other items (collectively, “Product Data Management” systems or PDM systems). More specifically, the disclosure is directed to production environment simulation.

### BACKGROUND OF THE DISCLOSURE

In In manufacturing plant design, three-dimensional (“3D”) digital models of manufacturing assets are used for a variety of manufacturing planning purposes. Examples of such usages includes, but are not limited by, manufacturing process analysis, manufacturing process simulation, equipment collision checks and virtual commissioning.

As used herein the terms manufacturing assets and devices denote any resource, machinery, part and/or any other object present in the manufacturing lines.

Manufacturing process planners use digital solutions to plan, validate and optimize production lines before building the lines, to minimize errors and shorten commissioning time.

Process planners are typically required during the phase of 3D digital modeling of the assets of the plant lines.

While digitally planning the production processes of manufacturing lines, the manufacturing simulation planners need to insert into the virtual scene a large variety of devices that are part of the production lines. Examples of plant devices include, but are not limited by, industrial robots and their tools, transportation assets like e.g. conveyors, turn tables, safety assets like e.g. fences, gates, automation assets like e.g. clamps, grippers, fixtures that grasp parts and more.

While simulating the process, many of these elements have a kinematic definition that controls the motion of these elements.

Some of these devices are kinematic devices with one or more kinematic capabilities which require a kinematic definition via kinematic descriptors of the kinematic chains. The kinematic device definitions enable to simulate, in the virtual environment, the kinematic motions of the kinematic device chains. An example of kinematic device is a clamp which opens its fingers before grasping a part and which closes such fingers for having a stable grasp of the part. For a simple clamp with two rigid fingers, the kinematics definition typically consists in assigning two inks descriptors to the two fingers and a joint descriptor to their mutual rotation axis positioned through their links node. As known in the art of kinematic chain definition, a joint is defined as a connection between two or more links at their nodes, which allows some motion, or potential motion, between the connected links. The following presents simplified definitions of terminology in order to provide a basic understanding of some aspects described herein. As used herein, a kinematic device may denote a device having a plurality of kinematic capabilities defined by a chain, whereby each kinematic capability is defined by descriptors describing a set of links and a set of joints of the chain. In other words, a kinematics descriptor may provide a full or a partial kinematic definition of a kinematic capability of a kinematic device. As used herein a kinematic descriptor may denote a link identifier, a link type, a joint identifier, a joint type, etc. A link identifier identifies a link. A link type denotes a type or a class of links within a device. The number of link types in a given kinematic device is the number of links which are geometrically different. For example, in the gripper 202 of FIG. 2 there are three links Ink1, Ink2, Ink3 and two types of links given that the two smaller links Ink2, Ink3 are of the same type.

Although there are many ready 3D device libraries that can be used by planners, most of these 3D models lack a kinematics definition and their virtual representations are hereby denoted with the term “virtual dummy devices” or “dummy devices”. Therefore, simulation planners are usually required to manually define the kinematics of these 3D dummy device models, a task which is time consuming, especially with manufacturing plants with a large number of kinematic devices like for example with automotive plants.

Typically, manufacturing process planners are solving this problem by assigning simulation engineers to maintain the resource library, so they manually model the required kinematics for each one of these resources. The experience of the simulation engineers help them to understand how the kinematics should be created and added to the devices. They are required to identify the links and joints of the devices and define them. This manual process consumes precious time of experienced users.

FIG. 2 schematically illustrates a block diagram of a typical manual analysis of the kinematics capability of a virtual gripper model (Prior Art).

The simulation engineer 203 analyzes the kinematic capability of a CAD model of a dummy gripper 201, whereby the dummy virtual device is lacking a kinematic definition. She loads into the virtual environment the gripper dummy model 301 and with her analysis she identifies the three links Ink1, Ink2, Ink3 and the joint jnt1, jnt2 (two translational joints, not shown) of the gripper's chain in order to build a kinematic gripper model 203 via a kinematics editor 304 comprising kinematic descriptors of the links Ink1, Ink2, link3 and the two joints j1,j2 which are the two connectors between link Ink1 and the other two links Ink2, link3. In this example, it is shown a specific example of kinematic chain, the skilled in the art knows that there are kinematic devices having different chains, with different numbers of links and different numbers and types of joints. Examples of kinematic joint types include, but are not limited by, prismatic joints, revolute or rotational joints, helical joints, spherical joints and planar joints. The dummy gripper model 301—i.e. the model without kinematics—may be defined in a CAD or mesh file format. The gripper model 303 with kinematics descriptors may be preferably defined in a file format allowing CAD geometry together with kinematics definition as for example jt. format files with both geometry and kinematics (which are usually stored in a cojt. folder) for the Process Simulate platform, or for example .prt format files for the NX platform, or any other kinematics object file formats which can be used by an industrial motion simulation software, e.g. a Computer Aided Robotic (“CAR”) tool like for example Process Simulate of the Siemens Digital Industries Software group.

As above explained, creating and maintaining definitions of kinematics capabilities and chain descriptors for a large variety of kinematic devices is a manual, tedious, repetitive and time-consuming task and requires the skills of experienced users.

Patent application PCT/IB2021/055391 teaches an inventive technique for automatically identifying kinematic capabilities in virtual devices.

Additional automatic techniques for identifying a kinematic capability in a virtual kinematic device are desirable.

### SUMMARY OF THE DISCLOSURE

Various disclosed embodiments include methods, systems, and computer readable mediums for identifying a kinematic capability in a virtual kinematic device, wherein a virtual kinematic device is a virtual device having at least one kinematic capability and wherein a kinematic capability is defined by at least two links of the virtual device. A method includes receiving input data; wherein the input data comprise data on a point cloud representation of a given virtual kinematic device: The method further includes applying a kinematic analyzer to the input data; wherein the kinematic analyzer is modeled with a function trained by a Machine Learning (“ML”) algorithm and the kinematic analyzer generates output data. The method further includes providing output data; wherein the output data comprises data for associating a subset of the points of the point cloud representation to a set of kinematic descriptors of at least one link identified on the point cloud representation of the given virtual kinematic device. The method further includes determining from the output data at least one identified kinematic capability in the given virtual kinematic device.

Various disclosed embodiments include methods, systems, and computer readable mediums for providing a trained function for identifying a kinematic capability in a virtual kinematic device, wherein a virtual kinematic device is a virtual device having at least one kinematic capability and wherein a kinematic capability is defined by at least two links of the virtual device. A method includes receiving input training data; wherein the input training data comprises data on a plurality of point cloud representations of a plurality of virtual kinematic devices, hereinafter called point cloud devices. The method further includes receiving output training data; wherein the output training data comprise, for each of the plurality of point cloud device, data for associating a subset of the cloud points to a set of kinematic descriptors of at least one link; wherein the output training data is related to the input training data. The method further includes training a function based on the input training data and the output training data via a ML algorithm. The method further includes providing the trained function for modeling a kinematic analyzer.

Various disclosed embodiments include methods, systems, and computer readable mediums for 15. A method for identifying, by a data processing system, a kinematic capability in a virtual kinematic device, wherein a virtual kinematic device is a virtual device having at least one kinematic capability and wherein a kinematic capability is defined by at least two links of the virtual device. A method includes receiving input training data; wherein the input training data comprises data on a plurality of point cloud representations of a plurality of virtual kinematic devices, hereinafter called point cloud devices. The method further includes receiving output training data; wherein the output training data comprise, for each of the plurality of point cloud device, data for associating a subset of the cloud points to a set of kinematic descriptors of at least one link; wherein the output training data is related to the input training data. The method further includes training a function based on the input training data and the output training data via a ML algorithm. The method further includes providing the trained function for modeling a kinematic analyzer. The method further includes receiving input data; wherein the input data comprise data on a point cloud representation of a given virtual kinematic device. The method further includes applying the kinematic analyzer to the input data; wherein the kinematic analyzer is modeled with a function trained by a ML algorithm and the kinematic analyzer generates output data. The method further includes providing output data; wherein the output data comprises data for associating a subset of the points of the point cloud representation to a set of kinematic descriptors of at least one link identified on the point cloud representation of the given virtual kinematic device. The method further includes determining from the output data at least one identified kinematic capability in the given virtual kinematic device.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiment disclosed as a basis for modifying or designing other structures for carrying out the same purposes of the present disclosure. Those skilled in the art will also realize that such equivalent constructions do not depart from the spirit and scope of the disclosure in its broadest form.

Before undertaking the DETAILED DESCRIPTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 illustrates a block diagram of a data processing system in which an embodiment can be implemented.

FIG. 2 schematically illustrates a block diagram of a typical manual analysis of the kinematics capability of a virtual gripper (Prior Art).

FIG. 3A schematically illustrates a block diagram for training a function with a ML algorithm for identifying a kinematic capability in a virtual kinematic device in accordance with disclosed embodiments.

FIG. 3B schematically illustrates exemplary input training data for training a function with a ML algorithm in accordance with disclosed embodiments.

FIG. 3C schematically illustrates exemplary output training data for training a function with a ML algorithm in accordance with disclosed embodiments.

FIG. 3D schematically illustrates exemplary output training data for training a function with a ML algorithm in accordance with disclosed embodiments.

FIG. 4 schematically illustrates a block diagram for identifying a kinematic capability in a virtual kinematic device in accordance with disclosed embodiments.

FIG. 5 schematically illustrates a block diagram for identifying a kinematic capability in a virtual kinematic device in accordance with other disclosed embodiments.

FIG. 6 illustrates a flowchart for identifying a kinematic capability in a virtual kinematic device in accordance with disclosed embodiments.

### DETAILED DESCRIPTION

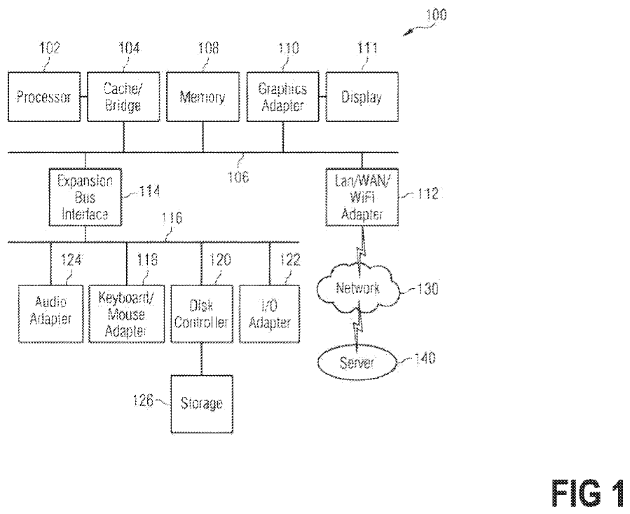

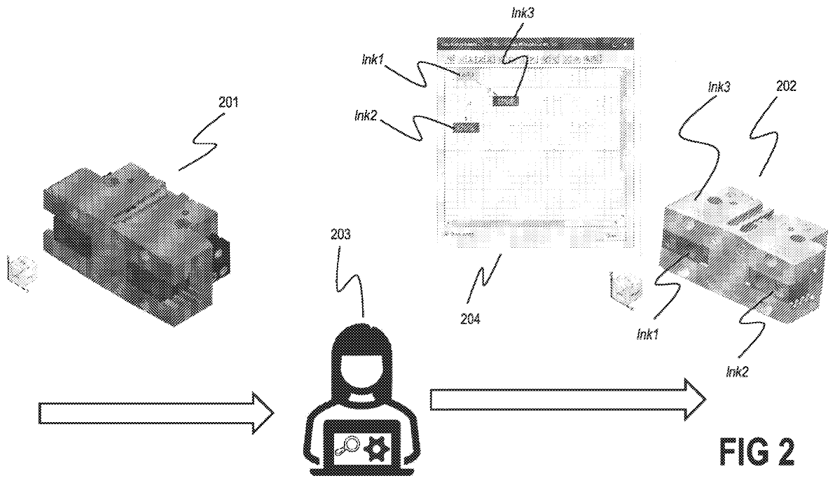

FIGS. 1 through 6, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

Furthermore, in the following the solution according to the embodiments is described with respect to methods and systems for identifying a kinematic capability in a virtual kinematic device as well as with respect to methods and systems for providing a trained function for identifying a kinematic capability in a virtual kinematic device.

Features, advantages, or alternative embodiments herein can be assigned to the other claimed objects and vice versa.

In other words, claims for methods and systems for providing a trained function for identifying a kinematic capability in a virtual kinematic device can be improved with features described or claimed in context of the methods and systems for identifying a kinematic capability in a virtual kinematic device and vice versa. In particular, the trained function of the methods and systems for identifying a kinematic capability in a virtual kinematic device can be adapted by the methods and systems for identifying a kinematic capability in a virtual kinematic device. Furthermore, the input data can comprise advantageous features and embodiments of the training input data, and vice versa. Furthermore, the output data can comprise advantageous features and embodiments of the output training data, and vice versa.

Previous techniques did not enable efficient kinematics capability identification in a virtual kinematic device. The embodiments disclosed herein provide numerous technical benefits, including but not limited to the following examples.

Embodiments enable to automatically identify and define kinematic capabilities of virtual kinematic devices.

Embodiments enable to identify and define the kinematic capabilities of virtual kinematic devices in a fast and efficient manner.

Embodiments minimizes the need of trained users for identifying kinematic capabilities of kinematic devices and reduce engineering time. Embodiments minimizes the quantity of “human errors” in defining the kinematic capabilities of virtual kinematic devices.

Embodiments may advantageously be used for a large variety of different types of kinematics devices.

Embodiments are based on a 3D dimensional analysis of the virtual device.

Embodiments enable an in-depth analysis of the virtual device via the point cloud transformation enabling to cover all device entities, even the hidden ones.

FIG. 1 illustrates a block diagram of a data processing system 100 in which an embodiment can be implemented, for example as a PDM system particularly configured by software or otherwise to perform the processes as described herein, and in particular as each one of a plurality of interconnected and communicating systems as described herein. The data processing system 100 illustrated can include a processor 102 connected to a level two cache/bridge 104, which is connected in turn to a local system bus 106. Local system bus 106 may be, for example, a peripheral component interconnect (PCI) architecture bus. Also connected to local system bus in the illustrated example are a main memory 108 and a graphics adapter 110. The graphics adapter 110 may be connected to display 111.

Other peripherals, such as local area network (LAN)/Wide Area Network/Wireless (e.g. WiFi) adapter 112, may also be connected to local system bus 106. Expansion bus interface 114 connects local system bus 106 to input/output (I/O) bus 116. I/O bus 116 is connected to keyboard/mouse adapter 118, disk controller 120, and I/O adapter 122. Disk controller 120 can be connected to a storage 126, which can be any suitable machine usable or machine readable storage medium, including but are not limited to nonvolatile, hard-coded type mediums such as read only memories (ROMs) or erasable, electrically programmable read only memories (EEPROMs), magnetic tape storage, and user-recordable type mediums such as floppy disks, hard disk drives and compact disk read only memories (CD-ROMs) or digital versatile disks (DVDs), and other known optical, electrical, or magnetic storage devices.

Also connected to I/O bus 116 in the example shown is audio adapter 124, to which speakers (not shown) may be connected for playing sounds. Keyboard/mouse adapter 118 provides a connection for a pointing device (not shown), such as a mouse, trackball, trackpointer, touchscreen, etc.

Those of ordinary skill in the art will appreciate that the hardware illustrated in FIG. 1 may vary for particular implementations. For example, other peripheral devices, such as an optical disk drive and the like, also may be used in addition or in place of the hardware illustrated. The illustrated example is provided for the purpose of explanation only and is not meant to imply architectural limitations with respect to the present disclosure.

A data processing system in accordance with an embodiment of the present disclosure can include an operating system employing a graphical user interface. The operating system permits multiple display windows to be presented in the graphical user interface simultaneously, with each display window providing an interface to a different application or to a different instance of the same application. A cursor in the graphical user interface may be manipulated by a user through the pointing device. The position of the cursor may be changed and/or an event, such as clicking a mouse button, generated to actuate a desired response.

One of various commercial operating systems, such as a version of Microsoft Windows™, a product of Microsoft Corporation located in Redmond, Wash. may be employed if suitably modified. The operating system is modified or created in accordance with the present disclosure as described.

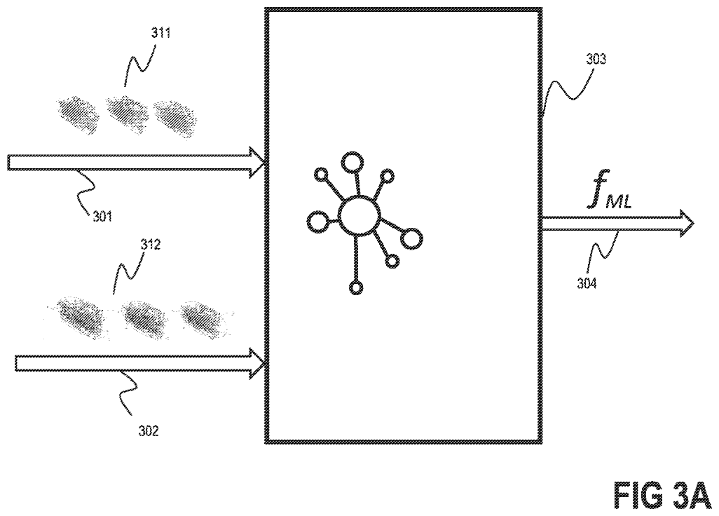

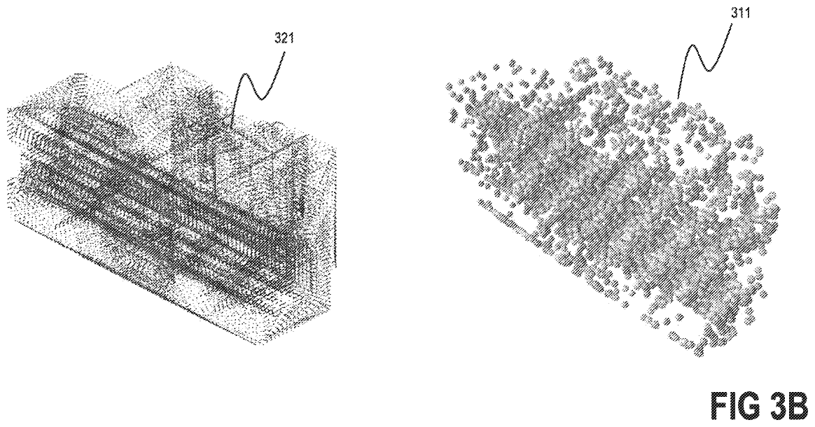

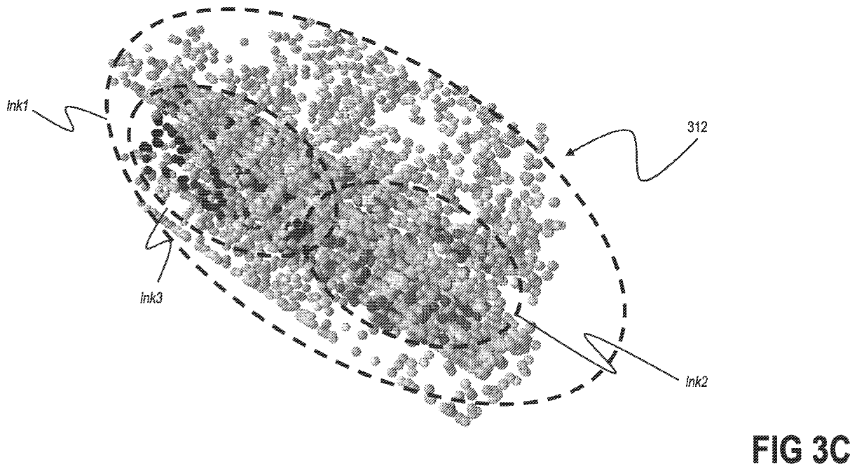

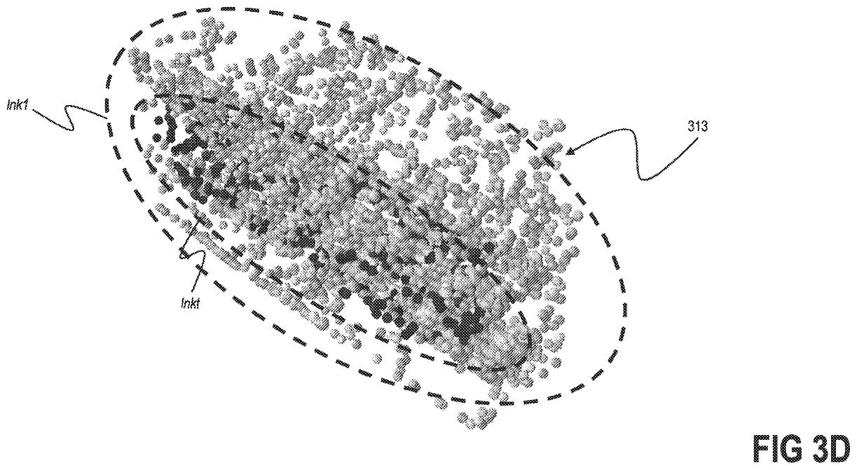

LAN/WAN/Wireless adapter 112 can be connected to a network 130 (not a part of data processing system 100), which can be any public or private data processing system network or combination of networks, as known to those of skill in the art, including the Internet. Data processing system 100 can communicate over network 130 with server system 140, which is also not part of data processing system 100, but can be implemented, for example, as a separate data processing system 100. FIG. 3 schematically illustrates a block diagram for training a function with a ML algorithm for modeling a false error detector in accordance with disclosed embodiments.

FIG. 3A schematically illustrates a block diagram for training a function with a ML algorithm for identifying a kinematic capability in a virtual kinematic device in accordance with disclosed embodiments.

In embodiments, inputs training data 301 are a set of point cloud representations 311 of a set of virtual devices. As used herein the terms “device point cloud” or “point cloud device” denote a point cloud representation of a virtual device and the term device 3D model denotes other 3D model representations like for example CAD models, mesh models, 3D scans etc. In embodiments, point cloud devices are received directly in other embodiments the point cloud devices are extracted from received 3D device models.

During the ML training phase, input training data 301 may be generated by extracting point cloud representations from 3D models of kinematic devices, herein exemplified with a gripper. The device point cloud 311 may thus be obtained by conversion from the corresponding device CAD or mesh model.

FIG. 3B schematically illustrates exemplary input training data for training a function with a ML algorithm in accordance with disclosed embodiments. In FIG. 3B are shown two versions of device point clouds, a point cloud with higher sampling 321 and a point cloud 311 with lower sampling. In embodiments, the point cloud device with lower sampling 312 is used.

The device cloud points 311 are usually defined with a list of points including each 3D coordinates and other information such as colors, surface normals, entity identifiers and other features. For example, the point cloud is defined by a list of points List <Point> where each point contains X,Y,Z and optionally other information such as colors, surface normals, entity identifiers and other features. It is noted than in the point cloud gripper 311 of FIG. 311, the color of the cloud points is uniform (even if the RGB color info is stored for each point) to exemplify in the illustration that such cloud points are not labeled yet and are not associated to a corresponding link descriptor, e.g. a link identifier or link type.

FIG. 3C schematically illustrates exemplary output training data for training a function with a ML algorithm in accordance with disclosed embodiments.

The output training data 302 are obtained by getting, for each point cloud device, kinematic descriptors Ink1, Ink2, Ink3 defining the chain elements—e.g. links and optionally joints—of the one or more kinematic capabilities of the device. For example, it is provided a list associating for each device cloud point its corresponding descriptor, link identifier or link type. For example, List-index of link, Point 1: link 1, Point 10; link 1, Point 250: link 2, Point 2000: link 3 etc.

In embodiments, the kinematic descriptors are describing the set of links of the point cloud devices and optionally they may describe the position of one or more joints (not shown). In embodiments, links and joint descriptors can comprise labels, identifiers and/or types.

In embodiments, the output training data may automatically be generated as labeled training dataset departing from the kinematic file of the device model or from a metadata file associated to the dummy device. In other embodiments, output training data may be manually generated by defining and labeling each link and joint with descriptor(s). In other embodiments, a mix of automatic and manual labeled dataset may advantageously be used.

In FIG. 3C, it is shown a point cloud gripper 312 whereby the cloud points are associated to one of the three link identifiers Ink1, Ink2, Ink3. The labeled output training data are shown for illustration purposes by marking the cloud points with different colors, e.g. light grey for link Ink1, dark grey for link Ink2 and black for link Ink3. Such link identifiers are an example of kinematic descriptors for defining the set of kinematic capabilities of the device.

Such link descriptors can be for example provided for training purposes by extracting data from the metadata of the device kinematic file or by analyzing the metadata with names and tags of the dummy device file.

Embodiments for generating output training data 302 may comprise loading a set virtual devices with already labeled links for example from already existing modeled kinematics devices and/or loading a set of virtual dummy devices into a virtual tool and label links in each dummy device.

Examples of labeling sources include, but are not limited by, language topology on the device entities, metadata on the device e.g. from manuals, work instructions, machinal drawings, existing kinematic data and/or manual labeling etc. In embodiments, naming conventions provided by the device vendors can advantageously be used to define which entity relates to each link Ink1, Ink2, Ink3 and this naming convention can be used for libraries which lack their own ones.

From the labeled devices, point cloud devices with labeled links data are extracted. In order to improve performances, the point cloud device 321 can preferably be down sampled—for example in FIG. 3B is shown a down sampled example 311 for the input (training) data.

In embodiments of the ML training phase, the input training data 301 for training the neural network are the point cloud devices 311 and the output training data 302 are the corresponding labeled data/metadata of the labeled point cloud device 312, e.g. the association between subsets of cloud point and corresponding link identifiers e.g. lnk1,lnk2,lnk3.

In embodiments, the result of the training process 303 is a trained neural network 304 capable of automatically detecting descriptors of kinematic links from a given set of dummy point cloud devices.

In embodiments, the trained neural network herein called “kinematic analyzer” is capable of associating one or more subsets of cloud points to their relevant corresponding link(s).

In embodiments, the training of the ML algorithm requires a labeled training dataset, a dataset for training the ML model as to be able to recognize the links in new dummy devices, also with different numbers of links.

Embodiments of a ML training algorithm include the following steps:
1) providing virtual devices with labeled links;
   1a) by loading dummy devices into the CAR tool and by labeling each device. Labeling sources may include: language topology on the device entities, device metadata on the device from manuals, work instructions, machinal drawings, existing kinematic data, manual labeling etc; or, alternatively,
   1b) by loading already modeled kinematics devices;
2) generating corresponding point cloud kinematics devices by conversion techniques for input/output training data. The point cloud may optionally be down sampled;
3) training the ML algorithm. For example, assume the input training data is the data on the list of device cloud points and the output is the list of point-link associations.

In embodiments, the point cloud devices may optionally be down sampled for performance optimizations. For example, assume there are circa 50 k points in a single point cloud device, although the whole 60 k point cloud can be used directly, much of the may not add much more information to the ML model, therefore, one can down sample the point cloud to circa 5 k points with down sampling techniques and/or other augmentation techniques. Advantageously, a large dataset training can be done faster.

### Input Training Data Example:

List <Point> Each point contains X, Y, Z optionally also RGB
Point 1: 10,20,30,56,67,233
Point 200: 132,241,320,0,200,200
etc.

### Corresponding Output Training Data Example:

List <index of link>
Point 1: link 1
Point 200: link 2
etc.

In other example embodiments, other types of additional information beside the RGB may be used such e.g. surface normals, entity identifiers etc.

Example of additional information include, but are not limited by, entity identifiers, surface normals, device structure information, other meta data information. In embodiments, such additional information may for example be automatically be extracted from the device CAD model which provide structure information on the device e.g. entities separation, naming, allocation etc.

In embodiments, a link may be a sub-portion of a link or a super portion of a link.

In embodiments of input (training) data preparation, an entity may get a random integer number which is unique for a given device and this umber is added to each cloud point, whereby the highest random number is the number of entities for the given device. Geometrically similar entities of the same device can optionally get the same random number. The assigned entity number may preferably not be related among different kinematic devices e.g. a specific entity in kinematic device A can get the number N and the entity with same name and same geometry of kinematic device B may preferably get a different number M. Before training, during the pre-processing phase, the numbers may preferably be normalized, e.g. to the 0-1 range, in order to shorten the training time and in order to improve results. In embodiments, the normalization step, e.g. in the 0-1 range, may be applied to all input (training) information data e.g. to the (X,Y,Z) coordinates and to the RGB/greyscale color.

In embodiments, during the execution phase, the input data are pre-processed by adding to the input data a random integer assigned to the device entities of the same device, optionally to be normalized, before appling the input data to the kinematic device.

In embodiments, the ML module may be trained upfront and provided as a trained module to the final users. In other embodiments, the users can do their ML training. The training can be done with the use of the CAR tool and also in the cloud.

In embodiments, the labeled observation data set is divided in a training set, validation set and a test set; the ML algorithm is fed with the training set and the prediction model receives inputs from the machine learner and from the validation set to output the statistics to help tune the training process as it goes and make decisions on when to stop it.

In embodiments, circa 70% of the dataset may be used as training dataset for the calibration of the weights of the neural network, circa 20% of the dataset may be used as validation dataset for control and monitor of the current training process and modify the training process if needed, and circa 10% of the dataset may be used later as test set, after the training and validation is done, for evaluating the accuracy of the ML algorithm.

In embodiments, the entire data preparation for the ML training procedure may be done automatically by a software application.

In embodiments, the output training data are automatically generated from the kinematics object files or from manual kinematics labelling or any combination thereof. In embodiments, the output training data are provided as metadata, text data, image data and/or any combination thereof.

In embodiments, the input/output training data comprise data in numerical format, in text format, in image format, in other format and/or in any combination thereof.

In embodiments, during the training phase, the ML algorithm learns to detect kinematic links of the device by “looking” at the point cloud devices.

In embodiments, the input training data and the output training data may be generated from a plurality of models of similar or different virtual kinematic devices.

Embodiments include a method and a system for providing a trained function for identifying a kinematic capability in a virtual kinematic device, wherein a kinematic device is a device having at least one kinematic capability.

Embodiments further comprise:
receiving input data; wherein input data comprise data on a point cloud representation of a given virtual kinematic device;
applying a kinematic analyzer to the input data; wherein the kinematic analyzer is modeled with a function trained by a ML algorithm and the kinematic analyzer generates output data;
providing output data; wherein the output data comprises data for associating a subset of the points of the point cloud representation to a set of kinematic descriptors of at least one link identified on the point cloud representation of the given virtual kinematic device;
determining from the output data the at least one identified kinematic capability in the given virtual kinematic device.

In embodiments, the input training data are generated by extracting point cloud representations 311 from dummy devices 3D models. In embodiments, the output training data are generated by extracting link labels from labeled point cloud devices 312.

In embodiments, the virtual kinematic devices belong to the same class or belong to a family of classes.

In embodiments, during the training phase with training data, the trained function can adapt to new circumstances and to detect and extrapolate patterns. In embodiments, the ML model may preferably be a classifying model and/or a point-wise segmentation.

In general, parameters of a trained function can be adapted by means of training. In particular, supervised training, semi-supervised training, unsupervised training, reinforcement learning and/or active learning can be used. Furthermore, representation learning (an alternative term is “feature learning”) can be used. In particular, the parameters of the trained functions can be adapted iteratively by several steps of training.

In particular, a trained function can comprise a neural network, a support vector machine, a decision tree and/or a Bayesian network, and/or the trained function can be based on k-means clustering, Qlearning, genetic algorithms and/or association rules.

In particular, a neural network can be a deep neural network, a convolutional neural network, or a convolutional deep neural network. Furthermore, a neural network can be an adversarial network, a deep adversarial network and/or a generative adversarial network.

In embodiments, the ML algorithm is a supervised model, for example a binary classifier which is classifying between true and pseudo error. In embodiments, other classifiers may be used for example logistic regressor, random forest classifier, xgboost classifier etc. In embodiments, a feed forward neural network via TensorFlow framework may be used.

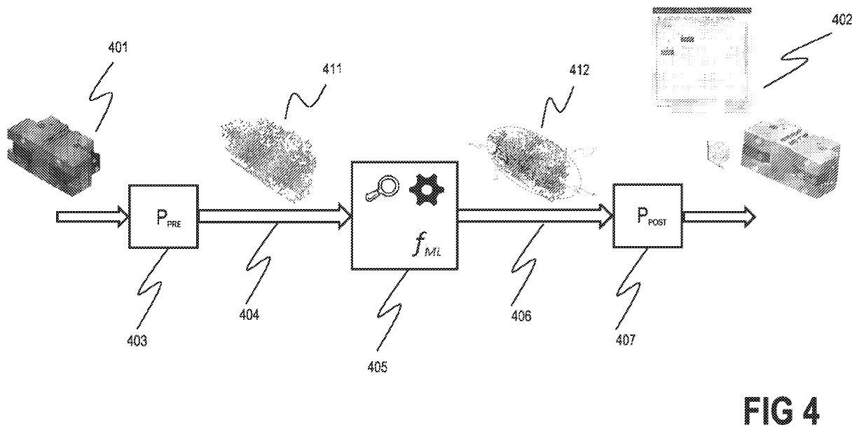

FIG. 4 schematically illustrates a block diagram for identifying a kinematic capability in a virtual kinematic device in accordance with disclosed embodiments. FIG. 4 schematically shows an example embodiment of neural network execution.

In embodiments, data on a 3D model of a virtual gripper 401 are provided. Such 3D model data can be provided in form of a CAD file or a mesh file e.g. a stl file format.

In embodiments, the provided 3D model data 401 are pre-processed 403 in order to extract point cloud representations 411 of the gripper. In embodiments, the cloud points may contain, in addition to the point coordinates also color or greyscale data for each point, surface normals, entity information and other information.

The input data 404, comprising device point cloud list, is applied to a kinematic analyzer 405 which provides outputs data 406. The output data comprises association device point clouds to the descriptors of the links lkn1, Ink2, lkn3 512 which correspond to the input data. The output data 406 are post-processed 407 in order to determine the links Ink1, Ink2, Ink3 in the 3D model of the gripper and, optionally, to define its joint(s). The information on the determined links and joint(s) may be added as kinematic definition to generate a kinematic file (e.g. in a cojt folder) from the departing dummy CAD file (e.g. a .jt file).

In embodiments, the point cloud of a new “unknown” dummy device is applied to the kinematic analyzer previously trained with a ML algorithm. The output of the kinematic analyzer are kinematic descriptors, e.g. link identifiers or link types for the relevant device cloud points.

In embodiments, each recognized link entity is labeled with its link identifier such as Ink1, Ink2, Ink3 etc.

By means of the kinematic analyzer, embodiments enable to determine where are the links and the joint(s) in order to defining them as part of the kinematic chain(s) of the analyzed device.

Embodiments enable to generate the definition of the kinematics capability of the analyzed device.

In embodiments, during the execution phase of the algorithm, a device's CAD file may be provided as input for pre-processing 403.

In embodiments, the file of the CAD model can be provided in a jt. format file, e.g. the native format of Process Simulate. In other embodiments, the file describing the device model can be provided into any other suitable file format describing a 3D model or sub-elements of it. In embodiments, this file in this latter format may preferably be converted into JT via a file converter, e.g. an existing one or ad-hoc created converter.

In embodiments, the output 406 of the kinematic analyzer 405 algorithm is processed 407 to determine a set of descriptors of the joints (and optionally links) for determining the kinematic chain(s) in the device 3D model 402.

In embodiments, the output of the kinematic analyzer with descriptors of the joints 412 is processed by a post-processing module 407. In embodiments, in the post processing module 407 includes determining the kinematic capabilities of the dummy device. In embodiments, the post processing module 407 includes identifying at least two device's links with two different identifiers associated to a same descriptor link type for example via clustering. In embodiments, the post processing module 407 includes additionally identifying a joint connecting the at least two links.

Embodiments of an algorithm for detecting a kinematic capability in a dummy device include one or more of the following steps:
loading new dummy device in Process Simulate
creating point cloud for this kinematics device, optional down-sampling
applying a kinematic analyzer to list of points of device entities e.g. entity A, entity B.
post processing may include assigning points to their common link identifier, refining the point which are not properly assigned, splitting link types with a classifier, finding one or more corresponding joints.

For example, for entities A and B inputs data are List <points>:
Entity A: points: 1,2,50,70,456,8888, 10000 . . .
Entity B: points: 13,22,70,71,73,73, 78 . . . .
Etc.
   After having applied the List <points> to the analyzer 405 the output data 406 include <link indexes>
Entity A: points: 1 (link 1), 2 (link 1),50 (link 1), 70 (link 1), 456 (link 1),8888 (link 2),10000 (link 1), . . . . Therefore even if point 8888 was wrongly assigned to link link 1 all points of the entity A are assigned to belong to link 1.

In embodiments, input (training) data are split in set of point clouds sub-portions corresponding to a set of entities of the device.

Embodiments enable to depart from a point cloud device comprising point positions and retrieve the point-link association.

Embodiments includes one or more of the following:
extracting point cloud from the CAD model
deep neural network analysis for point wise segmentation
optional, clustering ML model for detailed point cloud segmentation
analytic: post process matching for link separation
generate kinematic chain descriptor data
outcome data anaylzable within the kinematic editor

In embodiments, the entire kinematic chain(s) can be compiled and created so as to generate an output .JT file with kinematic definitions.

Embodiments have been described for a device like a gripper with three links and two joints. In embodiments, kinematic devices may have any numbers of links and joints. In embodiments, the device might be any device having at least one kinematic capability and chain.

In embodiments, the kinematic analyzer is a specific device analyzer and is trained and used specifically for a given type of kinematic device, e.g. specifically for certain type(s) of clamps, of grippers or of fixtures.

In other embodiments, the kinematic analyzer is a general device analyzer and is trained and is used to fit a broad family of different type of kinematic devices.

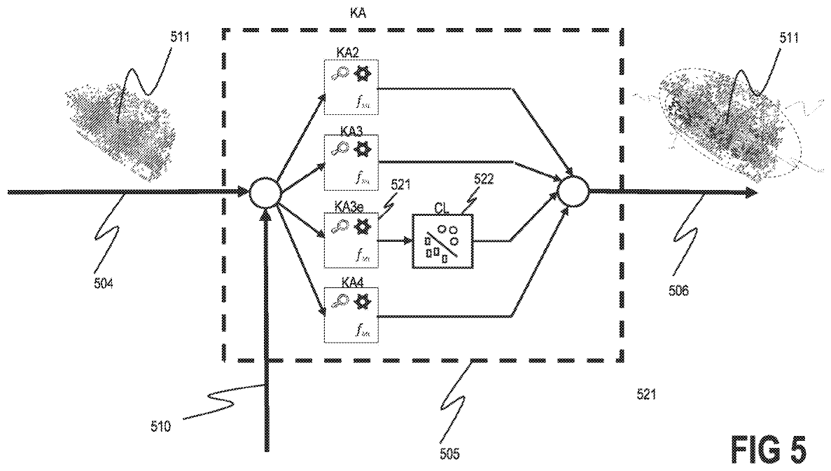

In embodiments, in order to select a suitable kinematic detector for a given specific device type, a pre-processing phase may be performed to analyze the type of received kinematic device, e.g. through received routing data as explained in FIG. 5 below.

In embodiments, a generic classifier detects which is the specific kinematic analyzer needs to be used, and then the specific analyzer is activated accordingly.

In embodiments, for a complex composite kinematic device—as for example the fixture containing dozens of clamps—the kinematic analysis can be performed by automatically extracting each simpler kinematic device, e.g. each clamp, and then feeding each simpler device automatically into a kinematic analyzer.

In other embodiments, the kinematic analyzer is capable of automatically analyzing composite kinematic devices.

FIG. 5 schematically illustrates a block diagram for identifying a kinematic capability in a virtual kinematic device in accordance with other disclosed embodiments. In embodiments, the kinematic analyzer 505 may be implemented as a combination of a set of specific analyzers routed according to the routing data 510.

The routing data might be information manually provided by a user (type of device, number of links and link types) or it might be data automatically detected by analyzing the dummy CAD file and its corresponding metadata.

For example, a user inputs routing data 510 including the number of links of a certain gripper so that the point cloud gripper 511 is routed for link(s) recognition to the corresponding kinematic analyzer. For example, if the gripper has two links there is a trained analyzer for two links KA2, for three links a kinematic analyzer of three links KA3 and for four links a kinematic analyzer of four links KA4.

In embodiments, when a device has a least two links belonging to the same link class, recognition capabilities of the analyzer can be enhanced by training a ML analyzer module to assign same link type identifier to links which have a similar shape. In FIG. 5 there is an example of usage of such a trained enhanced kinematic analyzer KA3e. In embodiments, the user inputs 510 that there is a gripper 511 having three links and two link types. The enhanced kinematic analyzer KA3e recognizes then two link types, Ink1,lnkt, where the cloud points identified with link lnkt belong to the two links Ink2, Ink3 of FIG. 3C which are the cloud points marked with the same black color in FIG. 3D. FIG. 3D schematically illustrates exemplary output training data for training a function with a ML algorithm in accordance with disclosed embodiments, for the specific case of a gripper having three links and two link types. The output 313 of the enhanced analyzer 521 is then inputted to a classifier module CL 522 which automatically splits the identified link lknt into different links Ink2, Ink3 like in the gripper 312 of FIG. 3C. Example of classification algorithms for splitting the links include unsupervised algorithms like clustering, k-means clustering.

In embodiments, an enhanced analyzer can preferably be utilized when the number of links and link types differ. In embodiments, when the number of links and the number of link types differ, the clustering post process module 522 may be automatically capable of deciding how many different clusters are present.

In accordance with the information received from the routing data 510, the device point cloud 511 is applied as input data 504 to its corresponding suitable kinematic analyzer e.g. KA2, KA3, KA3e, KA4. The output data contains link

Examples of routing data and use of an enhanced kinematic analyzer are provided below, where NL is the number of links, where NT is the number of link types. The number of links NL is received and if <NT is different than NL>, then the number of link types NT is received. In other embodiments, the number of NL is received and if <NT is different than NL>, then it may be received which of the types include more than one link and the classifiers determines automatically how many links are in this particular link type.

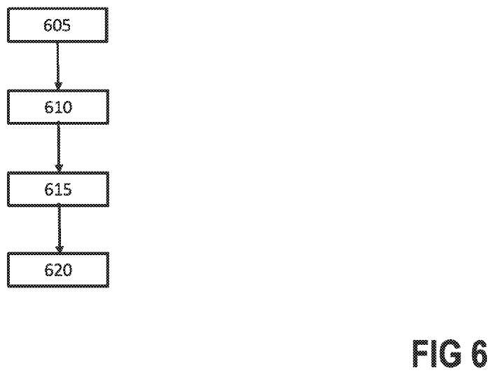

FIG. 6 illustrates a flowchart of a method for identifying a kinematic capability in a virtual kinematic device in accordance with disclosed embodiments. Such method can be performed, for example, by system 100 of FIG. 1 described above, but the “system” in the process below can be any apparatus configured to perform a process as described. The virtual kinematic device is a virtual device having at least one kinematic capability and wherein a kinematic capability is defined by a kinematic chain with a joint connecting at least two links of the virtual device or by at least two links, preferably interconnectable via joint.

In embodiments, the point cloud used for data training the ML algorithm and/or for execution of the algorithm may contain grayscale or RGB color information or other information such as entity data, surface normals and other relevant metadata.

At act 605, input data are received. The input data comprise data on a point cloud representation of a given virtual kinematic device. In embodiments, the input data are extracted from a CAD file of the device. In embodiments, the data on the point cloud representation may include coordinates data, color data, entity identifiers data and/or surface normals data.

At act 610, a kinematic analyzer is applied to the input data. The kinematic analyzer is modeled with a function trained by a ML algorithm and the kinematic analyzer generates output data.

At act 615, the output data is provided. The output data comprises data for associating a subset of the points of the point cloud representation to a set of kinematic descriptors of at least one link identified on the point cloud representation of the given virtual kinematic device. In embodiments, a kinematic descriptor may be a link identifier or a link type.

At act 620, it is determined, from the output data, at least one identified kinematic capability in the given virtual kinematic device. In embodiments, the kinematic capability is determined by identifying at least two device's links with two different identifiers associated to a same descriptor link type. In embodiments, the kinematic capability is determined by additionally identifying a joint connecting the at least two links.

In embodiments, routing data are received, they include the device type, the number of links, the link types, and/or the number of link types for selecting a specific suitable already trained kinematic analyzer.

Embodiments further include the step of controlling at least one manufacturing operation performed by a kinematic device in accordance with the outcomes of a computer implemented simulation of a corresponding set of virtual manufacturing operations of a corresponding virtual kinematic device.

In embodiments, at least one manufacturing operation performed by the kinematic device is controlled in accordance with the outcomes of a simulation of a set of manufacturing operations performed by the virtual kinematic device in a virtual environment of a computer simulation platform.

In embodiments, the term “receiving”, as used herein, can include retrieving from storage, receiving from another device or process, receiving via an interaction with a user or otherwise.

Those skilled in the art will recognize that, for simplicity and clarity, the full structure and operation of all data processing systems suitable for use with the present disclosure is not being illustrated or described herein. Instead, only so much of a data processing system as is unique to the present disclosure or necessary for an understanding of the present disclosure is illustrated and described. The remainder of the construction and operation of data processing system 100 may conform to any of the various current implementations and practices known in the art.

It is important to note that while the disclosure includes a description in the context of a fully functional system, those skilled in the art will appreciate that at least portions of the present disclosure are capable of being distributed in the form of instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable mediums include: nonvolatile, hard-coded type mediums such as read only memories (ROMs) or erasable, electrically programmable read only memories (EEPROMs), and user-recordable type mediums such as floppy disks, hard disk drives and compact disk read only memories (CD-ROMs) or digital versatile disks (DVDs).

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular element, step, or function is an essential element which must be included in the claim scope: the scope of patented subject matter is defined only by the allowed claims.

1-15. (canceled)

16. A method for identifying, by a data processing system, a kinematic capability in a virtual kinematic device, wherein the virtual kinematic device is a virtual device having at least one kinematic capability and wherein the at least one kinematic capability is defined by at least two links of the virtual device, the method comprises the steps of:
receiving input data containing data on a point cloud representation of a given virtual kinematic device;
applying a kinematic analyzer to the input data, wherein the kinematic analyzer is modeled with a function trained by a machine learning (ML) algorithm and the kinematic analyzer generates output data, wherein the output data includes data for associating a subset of points of the point cloud representation to a set of kinematic descriptors of at least one link identified on the point cloud representation of the given virtual kinematic device; and
determining from the output data at least one identified kinematic capability of the given virtual kinematic device.

17. The method according to claim 16, wherein a kinematic descriptor is a link identifier or a link type.

18. The method according to claim 16, wherein the data on the point cloud representation include data selected from the group consisting of:
coordinates data;
color data;
entity identifiers data; and
surface normals data.

19. The method according to claim 16, wherein the input data are extracted from a 3D model of the virtual kinematic device.

20. The method according to claim 16, wherein the at least one kinematic capability is determined by identifying at least two device's links with two different identifiers associated to a same descriptor link type.

21. The method according to claim 16, wherein the at least one kinematic capability is determined by additionally identifying a joint connecting the at least two links.

22. The method according to claim 16, wherein routing data are received for selecting an already trained said kinematic analyzer, the routing data include a device type, a number of links, link types, and a number of link types.

23. The method according to claim 16, which further comprises controlling at least one manufacturing operation performed by a virtual kinematic device in accordance with outcomes of a computer implemented simulation of a corresponding set of virtual manufacturing operations of the given virtual kinematic device.

24. A method for providing a trained function for identifying a kinematic capability in a virtual kinematic device, wherein the virtual kinematic device is a virtual device having at least one said kinematic capability and wherein the at least one kinematic capability is defined by at least two links of the virtual kinematic device, the method comprises the steps of:
receiving input training data, wherein the input training data includes data on a plurality of point cloud representations of a plurality of virtual kinematic devices, hereinafter called point cloud devices;
receiving output training data, wherein the output training data contains, for each of the plurality of point cloud devices, data for associating a subset of cloud points to a set of kinematic descriptors of at least one link, wherein the output training data is related to the input training data;
training a function based on the input training data and the output training data via a machine learning algorithm resulting in the trained function; and
providing the trained function for modeling a kinematic analyzer.

25. The method according to claim 24, wherein the data on the point cloud representations include data selected from the group consisting of:
coordinates data;
color data;
entity identifiers data; and
surface normals data.

26. A data processing system, comprising:
a processor; and
an accessible memory, the data processing system configured to:
receive input data, wherein the input data includes data on a point cloud representation of a given virtual kinematic device;
apply a kinematic analyzer to the input data, wherein the kinematic analyzer is modeled with a function trained by a machine learning algorithm and the kinematic analyzer generates output data, wherein the output data contains data for associating a subset of points of the point cloud representation to a set of kinematic descriptors of at least one link identified on the point cloud representation of the given virtual kinematic device; and
determine from the output data at least one identified kinematic capability in the given virtual kinematic device.

27. A non-transitory computer-readable medium encoded with executable instructions that, when executed, cause at least one data processing system to:
receive input data, wherein the input data includes data on a point cloud representation of a given virtual kinematic device;
apply a kinematic analyzer to the input data, wherein the kinematic analyzer is modeled with a function trained by a machine learning algorithm and the kinematic analyzer generates output data, wherein the output data contains data for associating a subset of points of the point cloud representation to a set of kinematic descriptors of at least one link identified on the point cloud representation of the given virtual kinematic device; and
determine from the output data at least one identified kinematic capability in the given virtual kinematic device.

28. A data processing system, comprising:
a processor; and
an accessible memory, said data processing system configured to access a non-transitory computer-readable medium encoded with executable instructions that, when executed, cause one or more data processing system to:
receive input training data, wherein the input training data contains data on a plurality of point cloud representations of a plurality of virtual kinematic devices, hereinafter called point cloud devices;
receive output training data, wherein the output training data contains, for each of the plurality of point cloud devices, data for associating a subset of cloud points to a set of kinematic descriptors of at least one link, wherein the output training data is related to the input training data;
train a function based on the input training data and the output training data via a machine learning algorithm resulting in a trained function; and
provide the trained function for modeling a kinematic analyzer.

29. A non-transitory computer-readable medium encoded with executable instructions that, when executed, cause at least one data processing system to:
receive input training data, wherein the input training data contains data on a plurality of point cloud representations of a plurality of virtual kinematic devices, hereinafter called point cloud devices;
receive output training data, wherein the output training data contains, for each of the plurality of point cloud devices, data for associating a subset of cloud points to a set of kinematic descriptors of at least one link, wherein the output training data is related to the input training data;
train a function based on the input training data and the output training data via a machine learning algorithm resulting in a trained function; and
provide the trained function for modeling a kinematic analyzer.

30. A method for identifying, by a data processing system, a kinematic capability in a virtual kinematic device, wherein the virtual kinematic device is a virtual device having at least one kinematic capability and wherein the at least one kinematic capability is defined by at least two links of the virtual kinematic device, the method comprises the steps of:
receiving input training data, wherein the input training data contains data on a plurality of point cloud representations of a plurality of virtual kinematic devices, hereinafter called point cloud devices;
receiving output training data, wherein the output training data contains, for each of the plurality of point cloud devices, data for associating a subset of cloud points to a set of kinematic descriptors of at least one link, wherein the output training data is related to the input training data;
training a function based on the input training data and the output training data via a machine learning algorithm resulting in a trained function;
providing the trained function for modeling a kinematic analyzer.
receiving input data; wherein the input data includes data on a point cloud representation of a given virtual kinematic device;
applying the kinematic analyzer to the input data; wherein the kinematic analyzer is modeled with the function trained by the machine learning algorithm and the kinematic analyzer generates output data, wherein the output data includes data for associating a subset of the cloud points of the point cloud representation to a set of the kinematic descriptors of the least one link identified on the point cloud representation of the given virtual kinematic device; and
determining from the output data at least one identified kinematic capability in the given virtual kinematic device.
